(19) United States
(12) Patent Application Publication
(10) Pub. No.: US 2017/0186856 A1
(43) Pub. Date: Jun. 29, 2017

(54) METHOD FOR MANUFACTURING LDMOS DEVICE

(71) Applicant: CSMC TECHNOLOGIES FAB1 CO., LTD., Jiangsu (CN)

(72) Inventor: Guangtao HAN, Jiangsu (CN)

(21) Appl. No.: 15/313,233

(22) PCT Filed: Aug. 18, 2015
(86) PCT No.: PCT/CN2015/087399

§ 371 Date: Nov. 22, 2016

(30) Foreign Application Priority Data
Sep. 2, 2014 (CN) 201410443311.5

(51) Int. Cl. H01L 29/66; H01L 21/266; H01L 29/10; H01L 29/40; H01L 29/423; H01L 29/78; H01L 21/265; H01L 21/28

(52) U.S. Cl. CPC H01L 29/66681; H01L 21/26586; H01L 21/266; H01L 21/28114; H01L 29/402; H01L 29/42368; H01L 29/42376; H01L 29/4238; H01L 29/7816; H01L 29/1037; H01L 29/1095; H01L 21/28035

(57) ABSTRACT

A method for manufacturing an LDMOS device includes: providing a semiconductor substrate (200), forming a drift region (201) in the semiconductor substrate (200), forming a gate material layer on the semiconductor substrate (200), and forming a negative photoresist layer (204) on the gate material layer; patterning the negative photoresist layer (204), and etching the gate material layer by using the patterned negative photoresist layer (204) as a mask so as to form a gate (203); forming a photoresist layer having an opening on the semiconductor substrate (200) and the patterned negative photoresist layer (204), the opening corresponding to a predetermined position for forming a body region (206); and injecting the body region (206) by using the gate (203) and the negative photoresist layer (204) located above the gate (203) as a self-alignment layer, so as to form a channel region.

### FIELD OF THE INVENTION

The present disclosure relates to a field of semiconductors, and more particularly relates to a manufacturing method of a LDMOS (Laterally Diffused Metal Oxide Semiconductor) device.

### BACKGROUND OF THE INVENTION

With the application of LDMOS in the integrated circuits becomes more and more widely, the requirement for LDMOS with higher breakdown voltage (off-BV) and lower on-resistance (Rdson) becomes increasingly urgent.

Generally speaking, the approach to reduce the Rdson of the LDMOS is to deplete the drift region according to a variety of RESURF theories, while continuously increasing the concentration of the drift region, such that a lower Rdson is obtained, and a higher off-BV is maintained. By this means, the relationship between Rdson and off-BV is close to the theoretical limit.

Using NLDMOS as an example, a conventional method to reduce the channel length includes: after etching the polysilicon gate and field plate, the photoresist is removed, and another photoresist is coated, a body region implantation region is exposed, a P-type body region implantation is performed using gate self-alignment technology. Then a channel region is formed by lateral diffusing the P-type body region through a certain thermal process. This method can make sure the channel region close to the source have the highest concentration, thus maintaining a higher off-BV while obtaining a shorter channel length.

Reference will now be made to FIGS. 1A to 1B to describe, in detail, the manufacturing method of the conventional NLDMOS.

Referring to FIG. 1A, firstly, a semiconductor substrate 100 is provided, a drift region is formed in the semiconductor substrate 100. A field oxide layer 101 is formed on the drift region. A polysilicon layer is formed on a surface of the semiconductor substrate 100 and the field oxide layer 101. A mask layer 103, which is a positive photoresist, is formed on the polysilicon layer. The mask layer 103 is patterned and the polysilicon layer is etched using an etching photomask for the polysilicon layer, thus forming the polysilicon gate and the field plate 102.

Referring to FIG. 1B, the mask layer 103 on the polysilicon gate and the field plate 102 is removed. A photoresist layer 104 is coated on the semiconductor substrate 100, the field oxide layer 101, and the polysilicon gate and the field plate 102. Next, the photoresist layer 104 is patterned using an etching photomask for the P-type body region implantation, so as to form a P-type implantation region pattern. A P-type body region implantation is performed using gate self-alignment technology. Then a channel region is formed by lateral diffusing the P-type body region through a certain thermal process, so as to form a P-type body region in the semiconductor substrate 100.

In the conventional method, after the body region implantation, the channel region can only be formed through a long time thermal process. The implantation energy cannot be too high due to the limitation of the thickness of the polysilicon gate, such that the channel region with a desired length is difficult to be formed. As a result, this polysilicon layer can only be used as a gate of LDMOS, because the threshold voltage Vt of the low voltage device cannot undergo a long thermal process. In addition, if the P-type body region is subject to a long time thermal process, the N-type impurity concentration of the drift region will be reduced due to the P-type impurity after lateral diffusing, thus causing Rdson to be increased.

### SUMMARY OF THE INVENTION

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter.

Accordingly, it is necessary to provide a method of manufacturing an LDMOS device with lower Rdson, which includes:

providing a semiconductor substrate, forming a drift region in the semiconductor substrate;

forming a gate material layer on the semiconductor substrate, and forming a negative photoresist layer on the gate material layer;

patterning the negative photoresist layer, and etching the gate material layer using the patterned negative photoresist layer as a mask, thus forming a gate;

forming a photoresist layer having an opening on the semiconductor substrate and the patterned negative photoresist layer, wherein the opening is corresponding to a position at which a body region is to be formed; and

performing a body region implantation using the gate and the negative photoresist layer above the gate as a self-alignment layer, thus forming a channel region.

According to the manufacturing method of the present invention, the formed channel region of the LDMOS has a less length, and the whole length of the LDMOS becomes smaller. The whole Rdson is lower by 10% to 30% comparing to that of the conventional NLDMOS, and the breakdown voltage off-BV is not affected, thus the performance of the LDMOS device is improved.

### BRIEF DESCRIPTION OF THE DRAWINGS

The components in the drawings are not necessarily drawn to scale, the emphasis instead being placed upon clearly illustrating the principles of the present disclosure. Moreover, in the drawings, like reference numerals designate corresponding parts throughout the views.

FIGS. 1A to 1B are cross-sectional views each showing a part of a method of manufacturing a NLDMOS device according to prior art;

FIGS. 2A to 2C are cross-sectional views each showing a part of a method of manufacturing a NLDMOS device according to an exemplary embodiment of the present invention;

FIG. 3 is a flow chart of a method of manufacturing a NLDMOS device according to an exemplary embodiment of the present invention.

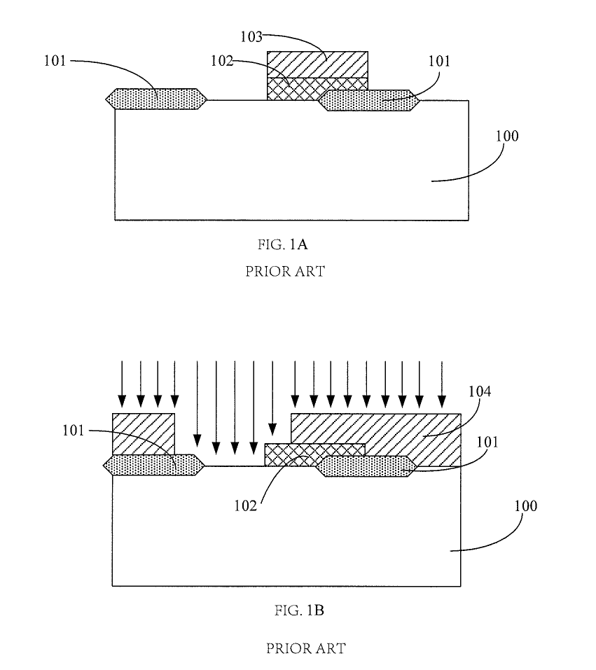

### DETAILED DESCRIPTION OF THE EMBODIMENTS

Embodiments of the invention are described more fully hereinafter with reference to the accompanying drawings. The various embodiments of the invention may, however, be embodied in many different forms and should not be construed as limited to the embodiments set forth herein.

In view of the above problems, the present invention provides a method of manufacturing a new LDMOS device.

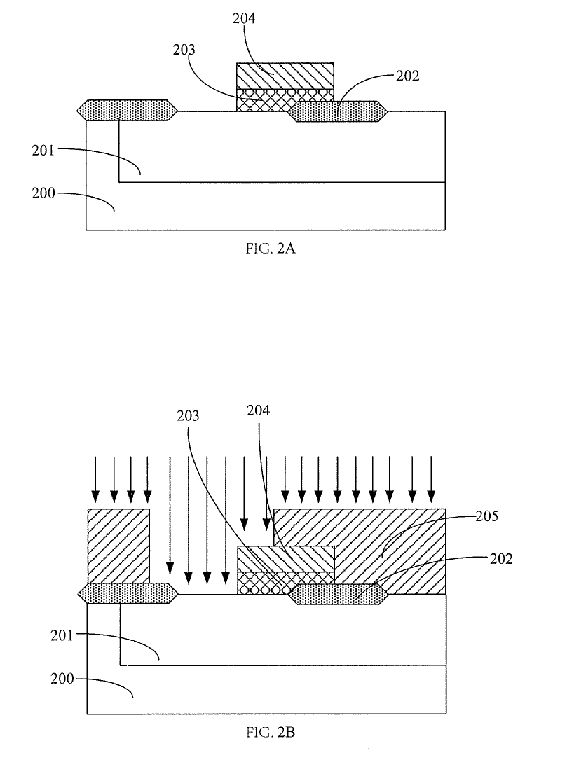

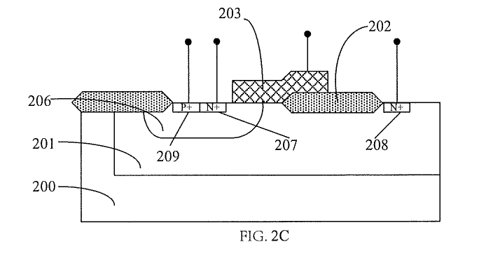

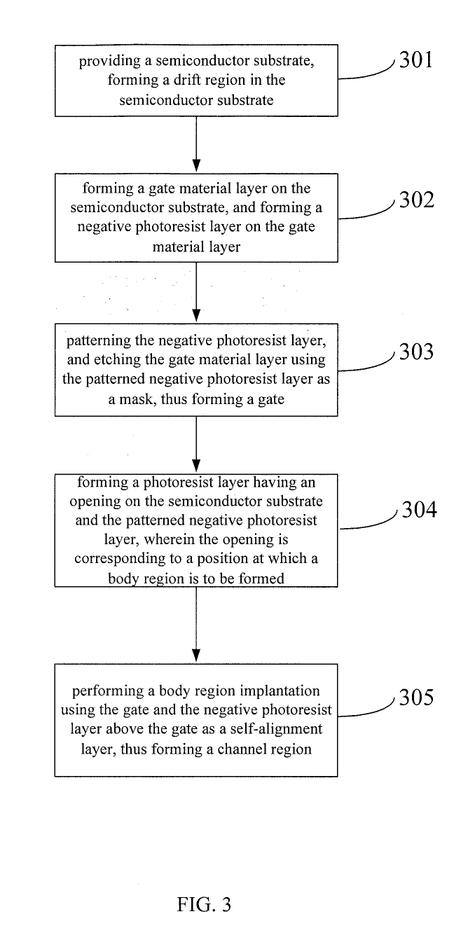

In one embodiment, the LDMOS device is an N-type LDMOS device. The present embodiment of manufacturing method of the N-type LDMOS device will be described in detail in conjunction with simplified cross-sectional views shown in FIGS. 2A to 2C and FIG. 3.

In step 301, a semiconductor substrate is provided, in which a drift region is formed.

Firstly, referring to FIG. 2A, a semiconductor substrate 200 is provided. The semiconductor substrate 200 can be made of silicon, silicon-on-insulator (SOI), stack silicon-on-insulator (SSOI), stack silicon germanium-on-insulator (S—SiGeOI), silicon germanium-on-insulator (SiGeOI), and germanium-on-insulator (GeOI), etc. With regarding to N-type LDMOS, the semiconductor substrate 200 is a P-type substrate.

An N-type ion doping is performed to the semiconductor substrate 200, so as to form an N-type drift region 201 in the substrate.

The doping is normally implemented by implantation. The higher desired doping concentration, the higher implantation dose during implantation. Generally speaking, a relatively low doping concentration of the drift region is equivalent to a high resistance layer formed between the source and the drain, which can increase the break-down voltage and reduce the parasitic capacitance between the source and drain, thus improving the frequency characteristics. For example, according to one embodiment of the present invention, the implantation impurity is phosphorus, and an implantation dose for the drift region 201 can be 1.0×10¹² to 1.0×10¹³ cm⁻².

A field oxide layer 202 is formed on the drift region 201. In one embodiment, the field oxide layer 202 is formed by local field oxide (Locos) process. Specifically, a thin pad oxide layer (not shown) is grown on the drift region and silicon nitride (not shown) is deposited, the field oxide layer 202 is thermally grown, the thin pad oxide layer and silicon nitride are etched by active region lithography, the photoresist is removed, the field oxide layer is thermally grown, the thin pad oxide layer and silicon nitride are removed, thus obtaining the final field oxide layer 202.

In step 302, a gate material layer is formed on the semiconductor substrate, and a negative photoresist layer is formed on the gate material layer.

In step 303, the negative photoresist layer is patterned, and the gate material layer is etched using the patterned negative photoresist layer as a mask, thus forming a gate.

The gate material layer is formed on the semiconductor substrate 200 and the field oxide layer 202, the negative photoresist layer 204 is formed on the gate material layer, the negative photoresist layer 204 is patterned, the gate material layer is etched using the patterned negative photoresist layer 204 as the mask, such that the gate and the field plate 203 covering partial field oxide layer 202 are formed.

Further, prior to forming the gate material layer, the method further includes forming a gate oxide layer on a surface of the semiconductor layer 200. The gate oxide layer (not shown) is formed using thermal oxidation process.

In one embodiment, when the gate material layer is a polysilicon layer, a negative photoresist layer is formed on the polysilicon layer. The negative photoresist layer is patterned using a mask for polysilicon etching. The polysilicon layer is etched to form the gate and the field plate positioned on partial field oxide layer. In this step, the negative photoresist, rather than normal positive photoresist, is employed. The reason why the negative photoresist is employed is because, after the etching for the polysilicon gate is completed, a P-type body region exposure process is required. During the P-type body region exposure process, it must be guaranteed that the photoresist layer on the polysilicon layer and the field plate will not be removed, while only the negative photoresist can be preserved during a developing process after exposure. Therefore, the negative photoresist layer positioned on the gate and the field plate is not removed in this step.

In step 304, a photoresist layer having an opening is formed on the semiconductor substrate and the patterned negative photoresist layer, and the opening is corresponding to a position at which a body region is to be formed.

Referring to FIG. 2B, a photoresist layer 205 having an opening is formed on the semiconductor substrate 200, the field oxide layer 201, and the patterned negative photoresist layer 204, and the opening is corresponding to a position at which a P-type body region is to be formed.

Specifically, the forming of the photoresist layer 205 having the opening includes the following steps: a photoresist layer is coated on the semiconductor substrate 200, the field oxide layer 201, and the patterned negative photoresist layer 204, the photoresist layer 205 having the opening is then formed through the exposure. The opening is corresponding to a position at which a P-type body region is to be formed. Since the photoresist layer on the gate is a negative photoresist layer, it can be preserved during a developing process after exposure.

In step 305, a body region implantation is performed using the gate and the negative photoresist layer above the gate as a self-alignment layer.

Referring to FIG. 2B again, the gate 203 and the negative photoresist layer 204 on the gate 203 are used as a self-alignment layer, and the P-type body region implantation is performed. The body region and the drift region have different conductivity types, e.g. when the drift region is N-type, the conductivity type of body region is P-type. Since the gate 203 and the negative photoresist layer 204 on the gate 203 are used as the self-alignment layer, the implantation energy of the P-type body region in this step can be relatively high, such that the channel region can be formed by a tilt angle implantation method. For example, according to one embodiment, an implantation dose for the body region can be 1.0×10¹² to 1.0×10¹³ cm⁻². Optionally, implantation energy of the body region implantation can be in a range of from 100 KeV to 800 KeV. Optionally, the P-type body region implantation can be performed by a tilt angle implantation method.

Drive-in is generally a high temperature long-term thermal annealing process, which is used for increasing the diffusion rate of the implanted ions. In the conventional method, a thermal process for annealing and drive-in is performed after ion implantation, so as to completely form the body region. According to the present invention, the body region implantation is performed by using high energy implantation or tilt angle implantation method, the channel region is formed by implanting the entire P-type body region without undergoing a lot of extra thermal process for annealing and drive-in, or even the thermal process for annealing and drive-in can be omitted, such that the polysilicon layer can serve as the gate of the low voltage portion. In addition, there is less lateral diffusion of the P-type impurity in the P-type body region, such that the concentration of the N-type drift region 201 will not be reduced, thus rendering a less Rdson.

Since the P-type body region implantation is performed using the gate 203 and the negative photoresist layer 204 on the gate 203 as a self-alignment layer, the accuracy requirements for alignment and exposure of the P-type body region are low. After the P-type body region implantation is completed, the negative photoresist layer 204 on the gate 203 can be removed along with the photoresist layer 205 having the opening.

Next, referring to FIG. 2C, N-type doping ions (e.g., phosphorus) are implanted in the P-type body region 206 to form an N-type source 207, and an N-type drain 208 is formed on a side thereof away from the P-type body region 206. The drain 208 is located outside the field oxide layer 202. After that, a P-type body lead-out region 209 is formed in the P-type body region 206. Then, the doping ions are activated by rapid thermal annealing. Contact holes can be continuously formed by subsequent processes, metal can be filled therein to form a metal interconnect lines, thus forming the source 207, the drain 208, the P-type lead-out region 209, and the gate 203.

Through the aforementioned steps, the manufacturing of NLDMOS is completed. Although the NLDMOS with the field region is illustrated as an example, the method can also be applied to the NLDMOS without field region (or STI), and the corresponding PLDMOS.

In summary, according to the manufacturing method of the present invention, the photoresist prior to polysilicon etching is configured to be negative photoresist, which will not be removed by exposure during subsequent exposing process. The negative photoresist will be preserved into the subsequent P-type body region photoresist exposure and implantation process, such that the negative photoresist as well as the gate can be used as the self-alignment layer for the P-type body region implantation, and the channel region can be formed by a high energy tilt angle implantation to the P-type body region. Accordingly, the formed channel region of the LDMOS has a less length, and the whole length of the LDMOS becomes smaller. The whole Rdson is lower by 10% to 30% comparing to the conventional NLDMOS, and the breakdown voltage off-BV is not affected, thus the performance of the LDMOS device is improved.

Although the description is illustrated and described herein with reference to certain embodiments, the description is not intended to be limited to the details shown. Modifications may be made in the details within the scope and range equivalents of the claims.

What is claimed is:

1. A method of manufacturing an LDMOS device, comprising:
forming a drift region in a semiconductor substrate;
forming a gate material layer on the semiconductor substrate, and forming a negative photoresist layer on the gate material layer;
patterning the negative photoresist layer, and etching the gate material layer using the patterned negative photoresist layer as a mask, thus forming a gate;
forming a photoresist layer having an opening on the semiconductor substrate and the patterned negative photoresist layer, wherein the opening is corresponding to a position at which a body region is to be formed; and
performing a body region implantation using the gate and the negative photoresist layer above the gate as a self-alignment layer, thus forming a channel region.

2. The method according to claim 1, wherein prior to forming the gate material layer, the method further comprises forming a field oxide layer above the drift region.

3. The method according to claim 2, wherein the gate extends to partially above the field oxide layer, thus forming a field plate.

4. The method according to claim 1, wherein implantation energy of the body region implantation is in a range of from 100 KeV to 800 KeV.

5. The method according to claim 1, wherein the body region implantation is performed by a tilt angle implantation method.

6. The method according to claim 1, wherein after performing the body region implantation, a thermal process for annealing and drive-in is not performed.

7. The method according to claim 1, wherein after the body region implantation is completed, the method further comprises simultaneously removing the negative photoresist layer on the gate and the photoresist layer having the opening.

8. The method according to claim 1, wherein the method is applicable to an NLDMOS with a field region, an NLDMOS with no field region or no shallow trench isolation structure, and a PLDMOS.

9. The method according to claim 1, wherein the gate is made of polysilicon.
